(19) United States
(12) Patent Application Publication
(10) Pub. No.: US 2014/0302660 A1
(43) Pub. Date: Oct. 9, 2014

(54) LOCAL INTERCONNECT TO A PROTECTION DIODE

(71) Applicant: GLOBALFOUNDRIES Inc., (US)

(72) Inventors: Yanxiang Liu, Wappingers Falls, NY (US); Jerome Ciavatti, Hopewell Junction, NY (US)

(73) Assignee: GLOBALFOUNDRIES Inc., Grand Cayman (KY)

(21) Appl. No.: 13/856,542

(22) Filed: Apr. 4, 2013

(51) Int. Cl. H01L 21/768; H01L 21/762

(52) U.S. Cl. CPC H01L 21/76877; H01L 21/76224
USPC 438/424

(57) ABSTRACT

Embodiments disclosed describe approaches for providing a local interconnection between a protection diode and a gate transistor in an integrated circuit (IC) device. Specifically, described is an IC device comprising: a protection diode formed in a substrate, a replacement metal gate (RMG) transistor formed over the substrate, a first contact formed over the protection diode (and optional trench silicide layer), a second contact formed over the RMG transistor, wherein the first contact extends to connect directly with the second contact, and a top metal layer (M1) formed over the first contact and the second contact. By extending the first contact from the protection diode directly to the gate transistor as a supplemental interconnect, any charges accumulated during formation of the second contact and the set of vias will be discharged by the protection diode.

### BACKGROUND

1. Technical Field

This invention relates generally to the field of semiconductor interconnect formation, and more particularly, to forming a local interconnection to a protection diode.

2. Related Art

Integrated circuits (ICs) are typically fabricated from one or more layers of different materials. Some layers, such as polysilicon layers, are used to form semiconductor devices, while other layers, such as patterned metal layers, provide electrical connections between semiconductor devices. Typical ICs include multiple patterned metal layers, with intervening inter-level dielectric layers for electrically insulating the metal layers.

It is well known that certain processes used in semiconductor fabrication, e.g., plasma processing, can cause charging of conductor films formed on a wafer surface. This phenomenon is sometimes referred to as the “antenna effect.” In some circumstances, the charge buildup can shift threshold voltage of the transistor or damage thin oxides of the transistor under the interconnect structures, either by shorting or sufficiently weakening the oxides so that they fail during normal device operation. For example, as shown in the prior art device 1 of FIG. 1, during metallization (i.e., when metal wires are laid across devices), a long floating metal line 6 can act as a temporary capacitor, collecting charges during fabrication steps, such as plasma etching. If the energy built up on the floating node has accumulated to a high enough point, the logic gate 4 may suffer permanent damage due to a breakdown of transistor gate oxide 8. Because of its adverse effects on yield, antenna effects are a critical issue in semiconductor processing.

There are numerous prior art approaches for reducing antenna effects in an integrated circuit. One prior art type of design change, shown in FIG. 2, involves providing a discharge path for each device input in the integrated circuit. A discharge path is typically created by connecting a device input through a diode 10, although other types of discharge paths may be used. Gate array implementations often have unused transistors that can be used for this purpose, as unused transistors may be converted into a diode by connecting the gate to either the drain or source. Insertion of diode 10 near a logic gate input pin 11 provides a discharge path to the substrate so that built-up charges cannot damage the transistor gate 12.

When diodes are used in replacement metal gate (RMG) technology, diode 10 is conventionally wired to a transistor by M1, as shown in FIG. 3. In this prior art approach, charging happens during formation of gate contact 14 and via 16 through the antenna effect. Transistor Vt could change due to varied metal gate process conditions, layout difference, and anneal processes. This Vt change can be suppressed by a high-pressure deuterium (D2) anneal, which is believed to provide neutralization or passivation of trapped charges in gate 12. However, as shown, the charging during gate contact/via formation is not protected by diode 10 because the diode has not been wired up to the transistor (i.e., M1 is formed later than gate contact/via).

### SUMMARY

In general, embodiments of the invention provide a local interconnection between a protection diode and a gate transistor in an integrated circuit (IC) device. Specifically, an IC device comprises: a protection diode formed in a substrate, a replacement metal gate (RMG) transistor formed over the substrate, a first contact formed over the protection diode (and optional trench silicide layer), a second contact formed over the RMG transistor, wherein the first contact extends to connect directly with the second contact, and a top metal layer (M1) formed over the first contact and the second contact. By extending the first contact from the protection diode directly to the gate transistor as a supplemental interconnect, any charges accumulated during formation of the second contact and the set of vias will be discharged by the protection diode.

One aspect of the present invention includes a method of forming an interconnect to a protection diode in a device, the method comprising: forming a protection diode in a substrate of the device; forming a replacement metal gate (RMG) transistor over the substrate; forming a first contact over the protection diode; forming a second contact over the RMG transistor, wherein the first contact extends to connect directly with the second contact; and forming a top metal layer (M1) over the first contact and the second contact.

Another aspect of the present invention includes a method of forming an interconnect to a protection diode in a device, the method comprising forming an integrated circuit (IC) structure including: a protection diode formed in a substrate of the device; a replacement metal gate (RMG) transistor formed over the substrate; a first contact formed over the protection diode; a second contact formed over the RMG transistor, wherein the first contact extends to connect directly with the second contact; and a top metal layer (M1) formed over the first contact and the second contact.

Another aspect of the present invention includes an integrated circuit (IC) device having an interconnect to a protection diode, the IC device comprising: a protection diode formed in a substrate; a replacement metal gate (RMG) transistor formed over the substrate; a first contact formed over the protection diode; a second contact formed over the gate transistor, wherein the first contact extends to connect directly with the second contact; and a top metal layer (M1) formed over the first contact and the second contact.

### BRIEF DESCRIPTION OF THE DRAWINGS

These and other features of this invention will be more readily understood from the following detailed description of the various aspects of the invention taken in conjunction with the accompanying drawings in which:

FIG. 1 shows a cross-sectional view of a prior art semiconductor device;

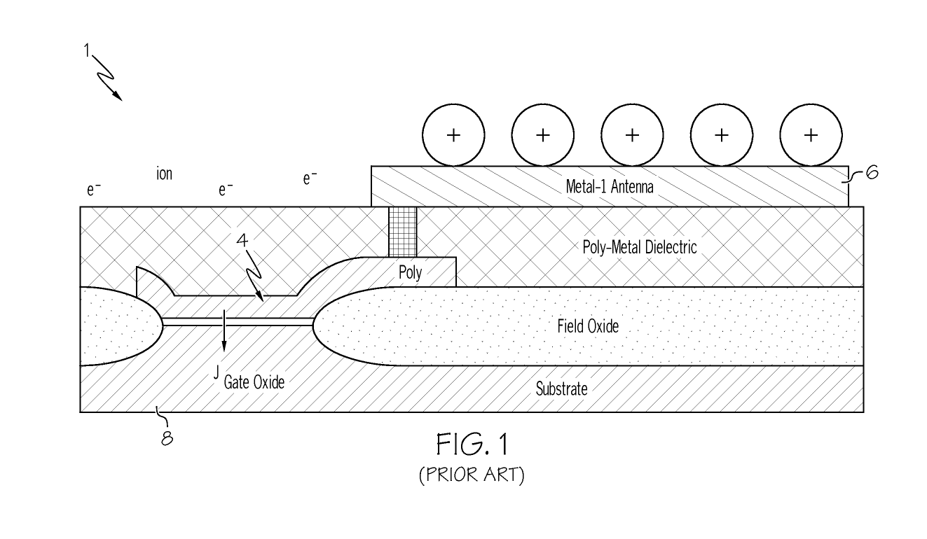

FIG. 2 shows a cross-sectional view of a prior art semiconductor device;

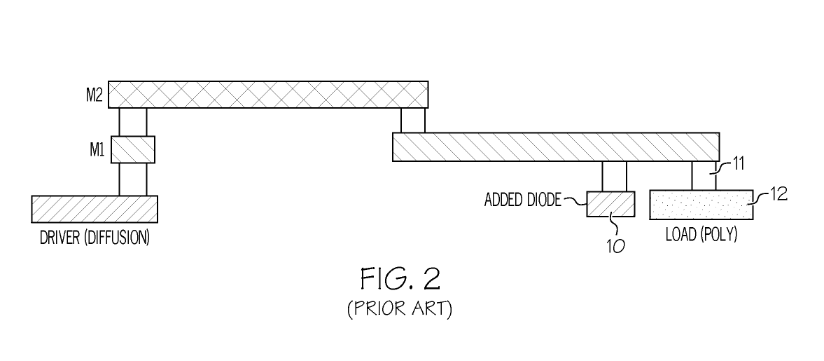

FIG. 3 shows a cross-sectional view of a prior art semiconductor device; and

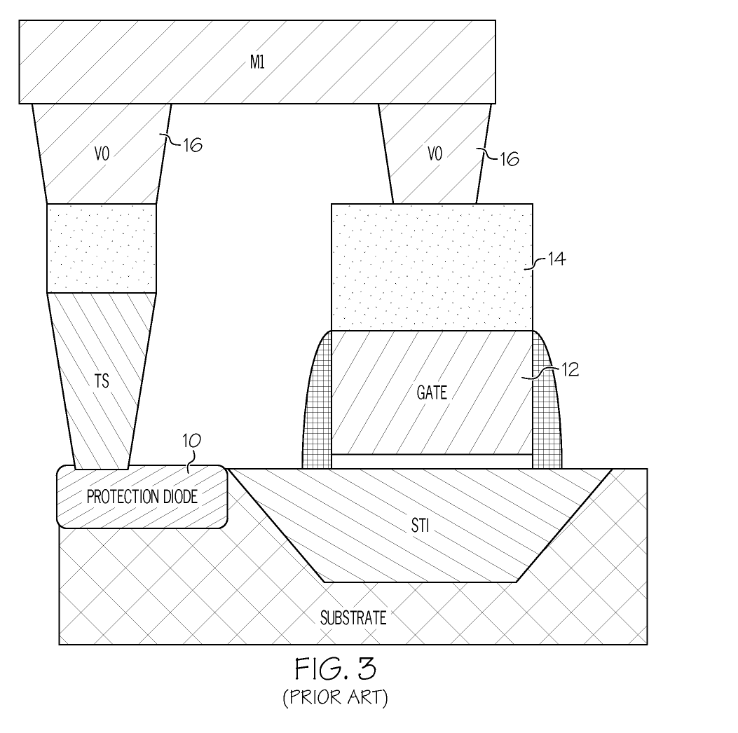

FIG. 4 shows a cross-sectional view of a local interconnection between a protection diode and a gate transistor in an IC device according to illustrative embodiments.

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

### DETAILED DESCRIPTION

Exemplary embodiments will now be described more fully herein with reference to the accompanying drawings, in which exemplary embodiments are shown. Described are methods and techniques used to provide a local interconnection between a protection diode and a gate transistor in an integrated circuit (IC) device. Specifically, described is an IC device comprising: a protection diode formed in a substrate, a replacement metal gate (RMG) transistor formed over the substrate, a first contact formed over the protection diode (and optional trench silicide layer), a second contact formed over the RMG transistor, wherein the first contact extends to connect directly with the second contact, and a top metal layer (M1) formed over the first contact and the second contact. By extending the first contact from the protection diode directly to the gate transistor as a supplemental interconnect, any charges accumulated during formation of the second contact and the set of vias will be discharged by the protection diode.

It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure, e.g., a first layer, is present on a second element, such as a second structure, e.g. a second layer, wherein intervening elements, such as an interface structure, e.g. interface layer, may be present between the first element and the second element.

As used herein, “depositing” may include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

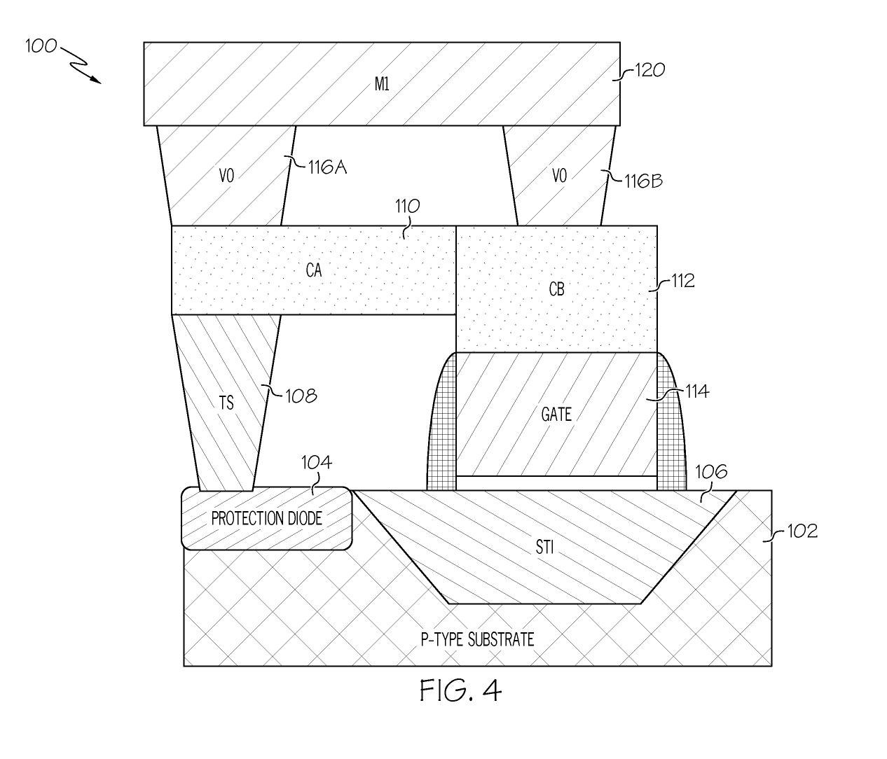

With reference again to the figures, FIG. 4 shows cross-sectional view of a device 100 (e.g., nFET) according to illustrative embodiments. Device 100 comprises a layered integrated circuit (IC) structure including a substrate 102 (e.g., a p-type substrate) containing a protection diode 104 formed therein. In exemplary embodiments, protection diode 104 is an N+/P diode, although this is not to be construed as limiting. Protection diode 104 is located in an active region of substrate 102 having good grounding. Substrate 102 may be any silicon containing substrate including, but not limited to Si, bulk Si, single crystal Si, polycrystalline Si, SiGe, amorphous Si, silicon-on-insulator substrates (SOI), SiGe-on-insulator (SGOI), strained-silicon-on-insulator, annealed poly Si, and poly Si line structures. In one embodiment, when substrate 102 is a silicon-on-insulator (SOI) or SiGe-on-insulator (SGOI) substrate, the thickness of the semiconducting Si-containing layer atop the buried insulating layer (not shown) may be 10 nm or greater. In one embodiment, the SOI or SGOI substrate may be fabricated using a thermal bonding process, or alternatively be fabricated by an ion implantation process, such as separation by ion implantation of oxygen (SIMOX).

As further shown, substrate 102 contains a source trench isolation (STI) region. As is known, a conventional STI process typically includes the following steps, simplified for the sake of brevity. First, a silicon nitride layer is thermally grown or deposited onto the silicon substrate. Next, using a lithography and etch process, the silicon nitride layer is selectively removed to produce a pattern where transistor source/drain areas are to be located. After patterning the source/drain areas, the substrate is etched to form trenches. After the trenches are formed, a liner is thermally grown on the exposed surfaces of the trench. The liner oxide is typically formed at a very high temperature in a hydrochloric (HCl) acid ambient. An insulator material, such as, silicon dioxide (SiO₂), is blanket deposited over the nitride layer and the liner oxide within the trench. The insulator material is polished to create a planar surface. The nitride layer is subsequently removed to leave the oxide structures within the trenches.

Next, an optional trench-silicide (TS) layer 108 is formed over protection diode 104, followed by a first contact (CA) 110, which is a contact on an active region of substrate 102. As shown, first contact 110 extends (e.g., horizontally) to connect with a second contact (CB) 112, which is a gate contact formed over a replacement metal gate (RMG) transistor 114. In one embodiment, RMG transistor 114 comprises a dummy gate, such as polysilicon, which is removed by dry/wet etching, followed by metal deposition. In another embodiment, a first polysilicon layer, bracketed by a pair of spacers, is removed selectively to a second polysilicon layer to create a trench between the spacers. The trench is filled with a first metal. The second polysilicon layer is then removed, and replaced with a second metal that differs from the first metal. However, it will be appreciated that this represents just two possible approaches, and that any number of techniques for forming RMG transistor 114 are possible within the scope of the invention.

As shown, second contact 112 is formed over RMG transistor 114, e.g., using the following non-limiting steps. First, a reactive ion etch (RIE) is performed to form an opening, which is filled with a conductive material (e.g., tungsten). Next, the conductive material is planarized to a desired height, e.g., using a chemical mechanical planarization (CMP) process. As understood to those skilled in the art, the CMP process involves contacting a material layer to be polished with a rotating polishing pad. An abrasive slurry comprising an abrasive suspended in an aqueous solution, which may also contain chemical constituents to achieve selectively, is disposed between the polishing pad and the material layer to be polished. The material layer to be polished is then polished away with the polish pad and slurry to achieve a desired removal.

Next, a set of vias 116A-B (i.e., vias formed before back-end-of-line) are formed over each of first contact 110 and second contact 112. In one embodiment, vias 116A-B are formed using an RIE, and subsequently filled with a conductive material. A top metal layer (M1) 120 is then formed over vias 116A-B to provide a second connection between protection diode 104 and RMG transistor 114. In this configuration, top metal layer 120 is still the main interconnection from protection diode 104 and RMG transistor 114 due to M1 routing flexibility. However, first contact 110 coupled to protection diode 104 is extended to RMG transistor 114 to serve as a supplemental local interconnect. Since protection diode 104 is connected to RMG transistor 114 through TS 108, first contact 110, and second contact 112, the charges accumulated during formation of second contact 112 and via 1168 will be discharged by protection diode 104. This configuration is further advantageous because protection diode 104 prevents Vt variation from RIE and CMP variations, improves Vt mismatch, and requires no additional masking/process complexity.

In various embodiments, design tools can be provided and configured to create the datasets used to pattern the semiconductor layers as described herein. For example data sets can be created to generate photomasks used during lithography operations to pattern the layers for structures as described herein. In one non-limiting embodiment, one or more masking structures are formed on an anti-reflective layer (not shown), for example, by spin coating. Masking structures include materials that is photosensitive at a wavelength range. For example, masking structures may include a deep ultraviolet (DUV) photoresist, a mid-ultraviolet (MUV) photoresist, an extreme ultraviolet (EUV) photoresist, or an electron beam (e-beam) photoresist. The material of the masking structure reacts to illumination and is chemically changed, for example, by cross-linking, in the wavelength range within which the masking structure is photosensitive. The masking structure may include a variety of types of masking structures. In one embodiment, the masking structure comprises refractive or reflective masking structures including, for example, optical, extreme ultraviolet (EUV), and/or x-ray technologies. An optical masking structure may generally include materials such as quartz or various types of silica including fused silica and chrome, chrome oxide, and/or chrome oxynitride or molybdenum silicide, but may include other materials in other embodiments. An EUV masking structure may include a ruthenium (Ru) capped molybdenum silicon (MoSi) multilayer blank among other materials and/or structures. EUV masking structures may also comprise a low thermal expansion material (LTEM). The masking structure may be used in immersion technologies in other embodiments.

Furthermore, such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance on which software runs or in which hardware is implemented. As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

Design tools used for implementing the approaches described herein may include a computer system (not shown) having a processing unit that executes computer program code, such as program code for a layout tool, which is stored in memory. While executing computer program code, the processing unit can read and/or write data to/from a memory unit and/or storage system. The storage system may comprise VCRs, DVRs, RAID arrays, USB hard drives, optical disk recorders, flash storage devices, and/or any other data processing and storage elements for storing and/or processing data. The computer system could also include I/O interfaces that communicate with one or more hardware components of a computer infrastructure that enable a user to interact with the computer system (e.g., a keyboard, a display, camera, etc.). The design tools of the computer infrastructure are configured to operate with a fabricator for designing and patterning features of an IC.

It is apparent that there has been provided approaches for forming a local interconnect to a protection diode in a device. While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

1. A method of forming an interconnect to a protection diode in a device, the method comprising:
forming a protection diode in a substrate of the device;
forming a replacement metal gate (RMG) transistor over the substrate;
forming a first contact over the protection diode;
forming a second contact over the RMG transistor, wherein the first contact extends to connect directly with the second contact; and
forming a top metal layer (M1) over the first contact and the second contact;
forming a first via over the first contact; and
forming a second via over the second contact, wherein M1 is coupled to the first contact and the second contact by the first via and the second via.

2. (canceled)

3. The method according to claim 1, further comprising forming a trench silicide (TS) layer over the protection diode.

4. The method according to claim 1, further comprising forming a shallow trench isolation region in the substrate.

5. The method according to claim 1, the forming the second contact comprising:
performing a reaction ion etch (RIE);
filling an opening formed from the RIE with a conductive material; and
performing a chemical mechanical planarization (CMP) process to remove a portion of the conductive material.

6. The method of claim 5, the conductive material comprising tungsten.

7. The method of claim 1, the forming the first via and the second via comprising performing a RIE.

8. The method of claim 7, further comprising filling the first via and the second via with a conductive material following the RIE.

9. A method of forming an interconnect to a protection diode in a device, the method comprising forming an integrated circuit (IC) structure, including:
a protection diode formed in a substrate of the device;
a replacement metal gate (RMG) transistor formed over the substrate;
a first contact formed over the protection diode;
a second contact formed over the RMG transistor, wherein the first contact extends to connect directly with the second contact;
a top metal layer (M1) formed over the first contact and the second contact;
forming a first via over the first contact; and
forming a second via over the second contact, wherein M1 is coupled to the first contact and the second contact by the first via and the second via.

10. (canceled)

11. The method according to claim 9, the IC structure further including a trench silicide (TS) layer formed over the protection diode.

12. The method according to claim 9, the IC structure further including a shallow trench isolation region formed in the substrate.

13. The method according to claim 10, the second contact formed by:
performing a reaction ion etch (RIE);
filling an opening formed from the RIE with a conductive material; and
performing a chemical mechanical planarization (CMP) process to remove a portion of the conductive material.

14. The method of claim 9, the first via and the second via formed by a RIE.

15. The method of claim 14, the IC structure further including a conductive material filling the first via and the second via following the RIE.

16. An integrated circuit (IC) device having an interconnect to a protection diode, the IC device comprising:
a protection diode formed in a substrate;
a replacement metal gate (RMG) transistor formed over the substrate;
a first contact formed over the protection diode;
a second contact formed over the gate transistor, wherein the first contact extends to connect directly with the second contact;
a top metal layer (M1) formed over the first contact and the second contact;
a first via formed over the first contact; and
a second via formed over the second contact, wherein Ml is coupled to the first contact and the second contact by the first via and the second via.

17. (canceled)

18. The IC device of claim 16, further comprising a trench silicide (TS) layer formed over the protection diode.

19. The IC device of claim 16, further comprising a source-shallow trench isolation region formed in the substrate.
